(19) United States
(12) Patent Application Publication
(10) Pub. No.: US 2006/0214154 A1
(43) Pub. Date: Sep. 28, 2006

(54) Polymeric gate dielectrics for organic thin film transistors and methods of making the same

(75) Inventors: Zhihao Yang, Webster, NY (US); Diane C. Freeman, Pittsford, NY (US); Amy E. Jasek, Rochester, NY (US); Shelby F. Nelson, Pittsford, NY (US)

Correspondence Address: Paul A. Leipold;Eastman Kodak Company, Patent Legal Staff, 343 State Street, Rochester, NY, 14650-2201, US

(73) Assignee: Eastman Kodak Company

(21) Appl. No.: 11/088,645

(22) Filed: Mar. 24, 2005

(51) Int. Cl. H01L 29/786; H01L 21/84

(52) U.S. Cl. 257/40; 438/99; 438/151; 257/66

(57) ABSTRACT

A thin film transistor comprises a layer of organic semiconductor material and spaced apart first and second contact means or electrodes in contact with said material. A multilayer dielectric comprises a first dielectric layer having a thickness of 200 nm to 500 nm, in contact with the gate electrode and a second dielectric layer in contact with the organic semiconductor material, and wherein the first dielectric layer comprise a continuous first polymeric material having a relatively higher dielectric constant less than 10 and the second dielectric layer comprises a continuous second non-fluorinated polymeric material having a relatively lower dielectric constant greater than 2.3. Further disclosed is a process for fabricating such a thin film transistor device, preferably by sublimation or solution-phase deposition onto a substrate, wherein the substrate temperature is no more than 100° C.

### FIELD OF THE INVENTION

The present invention relates to the use of multi-layered polymeric materials as gate dielectrics for making organic thin film transistors

### BACKGROUND OF THE INVENTION

Thin film transistors (TFTs) are widely used as a switching element in electronics, for example, in active-matrix liquid-crystal displays, smart cards, and a variety of other electronic devices and components thereof. The thin film transistor (TFT) is an example of a field effect transistor (FET). The best-known example of an FET is the MOSFET (Metal-Oxide-Semiconductor-FET), today's conventional switching element for high-speed applications. Presently, most thin film devices are made using amorphous silicon as the semiconductor. Amorphous silicon is a less expensive alternative to crystalline silicon. This fact is especially important for reducing the cost of transistors in large-area applications. Application of amorphous silicon is limited to low speed devices, however, since its maximum mobility (0.5-1.0 cm²/Vsec) is about a thousand times smaller than that of crystalline silicon.

Although amorphous silicon is less expensive than highly crystalline silicon for use in TFTs, amorphous silicon still has its drawbacks. The deposition of amorphous silicon, during the manufacture of transistors, requires relatively costly processes, such as plasma enhanced chemical vapor deposition and high temperatures (about 360° C.) to achieve the electrical characteristics sufficient for display applications. Such high processing temperatures disallow the use of substrates, for deposition, made of certain plastics that might otherwise be desirable for use in applications such as flexible displays.

In the past decade, organic materials have received attention as a potential alternative to inorganic materials such as amorphous silicon for use in semiconductor channels of TFTs. Organic semiconductor materials are simpler to process, especially those that are soluble in organic solvents and, therefore, capable of being applied to large areas by far less expensive processes, such as spin coating, dip coating and microcontact printing. Furthermore organic materials may be deposited at lower temperatures, opening up a wider range of substrate materials, including various plastics, for flexible electronic devices. Accordingly, thin film transistors made of organic materials can be viewed as a potential key technology for plastic circuitry in display drivers, portable computers, pagers, memory elements in transaction cards, and identification tags, where ease of fabrication, mechanical flexibility, and/or moderate operating temperatures are important considerations.

One area of concern in organic electronic devices is the gate dielectric. At present, most organic TFTs still use gate dielectric materials used in conventional Si-based semiconductor devices, such as SiO₂, SiNₓ, Al₂O₃, and Ta₂O₅, etc. Such materials are generally processed by thermal growth or plasma enhanced chemical vapor deposition, and normally require vacuum conditions, and sometimes high temperatures (above 300° C.) for processing. Such processes are, therefore, expensive and can be incompatible with plastic substrate materials which generally require the process temperature lower than 200° C. Accordingly, there is a need for gate dielectric materials that can be processed inexpensively at low temperature for making organic TFTs on various plastics, for example, for use in flexible electronic devices.

U.S. Pat. No. 6,774,393 B2 to Murti et al. discloses, as an insulating layer in field effect transistors, organic polymers such as polyesters, polycarbonates, poly(vinyl phenol), polyimides, polystyrene, poly(methacrylate)s, poly(acrylates), epoxy resins, and the like. Murti et al. state that the thickness of the insulating layer is typically from 10 to 500 nanometers depending on the dielectric constant of the dielectric material used.

U.S. Pat. No. 2004/0056246 A1 to Yan et al. discloses an organic thin film transistor (OTFT) having a first insulation layer and a second insulation layer with different dielectric constants. Yan et al. discloses the use of two insulation layers to reduce gate leakage, not for increasing mobility of the semiconductor material. Yan et al. discloses that the dielectric constant of the first (lower) insulation layer is at least three times higher than that of the second (upper) insulation layer. The former can be made of polyvinylidene fluoride whereas the second can be made of poly(methyl methacrylate), polyimide, or epoxide resin.

Joonhyung Park et al., “A polymer gate dielectric for high-mobility polymer thin-film transistors and solvent effects,” Applied Physics letters, Vol. 85, No. 15 (11 Oct. 2004), describes a gate dielectric of poly(2-hydroxyethyl methacrylate) (“PHEMA”) and the effects on polymer interfaces of solvents used in making the thin-film transistors.

Prior work has indicated that properties of the dielectric material and the interface between the semiconductor and the dielectric can have significant effects on the performance of a TFT. For better performance of TFT devices, the gate dielectric is preferred to be a high-dielectric-constant (“high-K”) material. However, for the TFTs made with organic semiconductor materials, it is often found that the high-K gate-dielectric materials may adversely affect the performance of the organic semiconductors, as disclosed by A. F. Stassen et al. “Influence of the Gate Dielectric on the Mobility of Rubrene Single Crystal Field-Effect Transistors” Applied Physics letters, Vol. 85, No. 17, p3899 (25 Oct. 2004). Janos Veres et al., “Low-k Insulators as the Choice of Dielectrics in Organic Field-Effect transistors,” Advanced Functional Materials 2003, 13, No. 3 March, describe the effect of the choice of the gate insulator material on the operation of organic field-effect transistors. Transistors were prepared with a range of organic insulators such as polyhydroxystyrene, polymethylmethacrylate (PMMA), and polyvinyl alcohol (PVA), polyisobutylene, poly(4-methyl-1-pentene), copolymers of polypropylene, fluoropolymer, and poly[propylene-co-(1-butene)]. Veres et al. found that in their system, using a range of amorphous organic semiconductors, low-k insulators improved device performance. WO 03/052841 A1 discloses combinations of different dielectric layers.

There is a need in the art for new and improved organic dielectrics for use in organic thin film transistor materials. It is desirable that such dielectrics have low surface roughness, high breakdown voltage, solution processability, and low leakage current. There is especially a need for dielectrics that improve the operating mobilities and current on/off ratios of semiconductor materials in organic thin film transistor devices.

### SUMMARY OF THE INVENTION

The present invention is directed to an article comprising, in a thin film transistor, more particularly a field effect transistor, a thin film of organic semiconductor material, a multi-layer dielectric, a gate electrode, a source electrode, and a drain electrode, wherein the multi-layer dielectric layer, the gate electrode, the thin film of organic semiconductor material, the source electrode, and the drain electrode are in any sequence as long as the gate electrode and the film of organic semiconductor material both contact the multi-layer dielectric, and the source electrode and the drain electrode both contact the thin film of the organic semiconductor material. The multilayer dielectric comprises a first dielectric layer having a thickness of 100 to 500 nm, preferably 200 to 400 nm, in contact with the gate electrode and a second dielectric layer having a thickness of 5 nm to 50 nm, preferably 8 to 40 nm, in contact with the organic semiconductor material. The first dielectric layer comprises a continuous first polymeric material having a relatively higher dielectric constant less than 10 and the second dielectric layer comprises a continuous second non-fluorinated polymeric material having a relatively lower dielectric constant greater than 2.3, wherein the difference in the dielectric constants is at least 0.2. The organic semiconductor material may be an N-type or P-type semiconductor material.

The present gate dielectric multi-layer film results in improved performance of organic semiconductor materials in OTFTs compared to single-layer high-K gate dielectrics.

The invention is also directed to a process for fabricating a thin film semiconductor device, comprising, not necessarily in the following order, the steps of:
(a) forming a gate electrode spaced apart from the semiconductor material;
(b) forming a continuous first layer of a first polymeric dielectric material having a thickness of 100 to 500 nm in contact with the gate electrode;
(c) forming a continuous second layer of a second non-fluorinated polymeric dielectric material having a thickness of 5 nm to 50 nm over the first layer of a dielectric not in contact with the gate electrode, wherein the first dielectric layer comprises a continuous first polymeric material having a relatively higher dielectric constant less than 10 and the second polymeric dielectric layer comprises a continuous second non-fluorinated polymeric material having a relatively lower dielectric constant greater than 2.3, wherein the difference in the dielectric constants is at least 0.2;
(d) depositing, onto a substrate, a thin film of organic semiconductor material; and
(e) forming a spaced apart source electrode and drain electrode, wherein the source electrode and the drain electrode are separated by, and electrically connected with, the semiconductor film.

As used herein, “a” or “an” or “the” are used interchangeably with “at least one,” to mean “one or more” of the element being modified.

As used herein, the terms “over,” “above,” and “under” and the like, with respect to layers in the thin film transistor, refer to the order of the layers over the support, but do not necessarily indicate that the layers are immediately adjacent or that there are no intermediate layers.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical or analogous features that are common to the figures, and wherein:

FIG. 1 illustrates a cross-sectional view of a typical organic thin film transistor having a bottom contact configuration; and

FIG. 2 illustrates a cross-sectional view of a typical organic thin film transistor having a top contact configuration.

### DESCRIPTION OF THE INVENTION

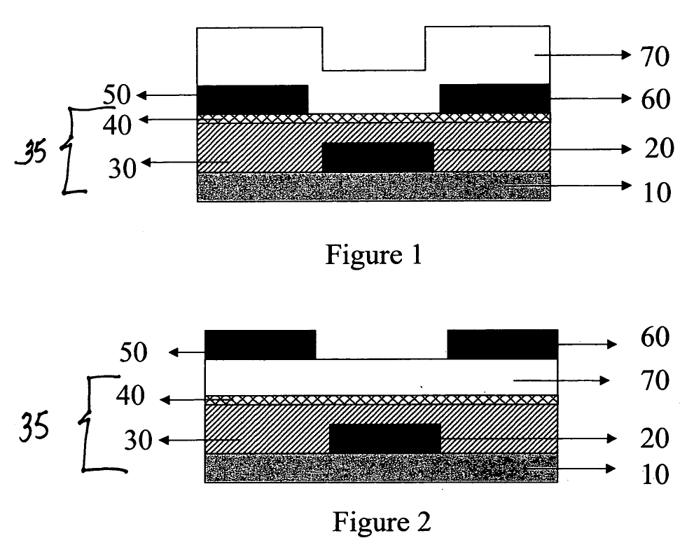

Cross-sectional views of typical organic thin film transistor are shown in FIGS. 1 and 2, wherein FIG. 1 illustrates a typical bottom contact configuration and FIG. 2 illustrates a typical top contact configuration.

Each thin film transistor (TFT) in FIGS. 1 and 2 contains a source electrode 50, a drain electrode 60, a gate electrode 20, a substrate 10, a semiconductor 70 in the form of a film connecting the source electrode 50 to drain electrode 60, and a gate dielectric 35 consisting of a high-K dielectric layer 30 and a low-K dielectric layer 40 as described herein.

When the TFT operates in an accumulation mode, the charges injected from the source electrode into the semiconductor are mobile and a current flows from source to drain, mainly in a thin channel region within about 100 Angstroms of the semiconductor-dielectric interface. See A. Dodabalapur, L. Torsi H. E. Katz, Science 1995, 268, 270, hereby incorporated by reference. In the configuration of FIG. 1, the charge need only be injected laterally from the source electrode 50 to form the channel. In the absence of a gate field the channel ideally has few charge carriers; as a result there is ideally no source-drain conduction.

The off current is defined as the current flowing between the source electrode 50 and the drain electrode 60 when charge has not been intentionally injected into the channel by the application of a gate voltage. For an accumulation-mode TFT, this occurs for a gate-source voltage more negative, assuming an n-channel, than a certain voltage known as the threshold voltage. See Sze in Semiconductor Devices—Physics and Technology, John Wiley & Sons (1981), pages 438-443. The on current is defined as the current flowing between the source electrode 50 and the drain electrode 60 when charge carriers have been accumulated intentionally in the channel by application of an appropriate voltage to the gate electrode 20, and the channel is conducting. For an n-channel accumulation-mode TFT, this occurs at gate-source voltage more positive than the threshold voltage. It is desirable for this threshold voltage to be zero, or slightly positive, for n-channel operation. Switching between on and off is accomplished by the application and removal of an electric field from the gate electrode 20 across the gate dielectric 35 to the semiconductor-dielectric interface (not shown), effectively charging a capacitor.

In yet another embodiment of the present invention, source drain and gate can all be on a common substrate and the gate dielectric can enclose gate electrode such that gate electrode is electrically insulated from source electrode and drain electrode, and the semiconductor layer can be positioned over the source, drain and dielectric.

The skilled artisan will recognize other structures can be constructed and/or intermediate surface modifying layers can be interposed between the above-described components of the thin film transistor. In most embodiments, a field effect transistor comprises an insulating layer, a gate electrode, a semiconductor layer comprising an organic material as described herein, a source electrode, and a drain electrode, wherein the dielectric, the gate electrode, the semiconductor layer, the source electrode, and the drain electrode are in any sequence as long as the gate electrode and the semiconductor layer both contact the insulating layer, and the source electrode and the drain electrode both contact the semiconductor layer.

A support can be used for supporting the OTFT during manufacturing, testing, and/or use. The skilled artisan will appreciate that a support selected for commercial embodiments may be different from one selected for testing or screening various embodiments. In some embodiments, the support does not provide any necessary electrical function for the TFT. This type of support is termed a “non-participating support” in this document. Useful materials can include organic or inorganic materials. For example, the support may comprise inorganic glasses, ceramic foils, polymeric materials, filled polymeric materials, coated metallic foils, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbomenes, polyphenyleneoxides, poly(ethylene naphthalenedicarboxylate) (PEN), poly(ethylene terephthalate) (PET), poly(phenylene sulfide) (PPS), and fiber-reinforced plastics (FRP).

A flexible support is used in some embodiments of the present invention. This allows for roll processing, which may be continuous, providing economy of scale and economy of manufacturing over flat and/or rigid supports. The flexible support chosen preferably is capable of wrapping around the circumference of a cylinder of less than about 50 cm diameter, more preferably 25 cm diameter, most preferably 10 cm diameter, without distorting or breaking, using low force as by unaided hands. The preferred flexible support may be rolled upon itself.

In some embodiments of the invention, the support is optional. For example, in a top construction as in FIG. 2, when the gate electrode and/or gate dielectric provides sufficient support for the intended use of the resultant TFT, the support is not required. In addition, the support may be combined with a temporary support. In such an embodiment, a support may be detachably adhered or mechanically affixed to the support, such as when the support is desired for a temporary purpose, e.g., manufacturing, transport, testing, and/or storage. For example, a flexible polymeric support may be adhered to a rigid glass support, which support could be removed.

The gate electrode can be any useful conductive material. A variety of gate materials known in the art, are also suitable, including metals, degenerately doped semiconductors, conducting polymers, and printable materials such as carbon ink or silver-epoxy. For example, the gate electrode may comprise doped silicon, or a metal, such as aluminum, chromium, gold, silver, nickel, palladium, platinum, tantalum, and titanium. Conductive polymers also can be used, for example polyaniline, poly(3,4-ethylenedioxythiophene)/poly(styrene sulfonate) (PEDOT:PSS). In addition, alloys, combinations, and multilayers of these materials may be useful.

In some embodiments of the invention, the same material can provide the gate electrode function and also provide the support function of the support. For example, doped silicon can function as the gate electrode and support the OTFT.

The gate dielectric is provided on the gate electrode. This gate dielectric electrically insulates the gate electrode from the balance of the OTFT device. Thus, the gate dielectric comprises an electrically insulating material.

As indicated above, the thin film transistor of the present invention comprises a multi-layer dielectric comprising a first dielectric layer having a thickness of 100 to 500 nm, in contact with the gate electrode and a second dielectric layer having a thickness of 5 nm to 40 nm, preferably 10 nm to 20 nm, in contact with the organic semiconductor material, and wherein the first dielectric layer comprise a continuous first polymeric material having a relatively higher dielectric constant and the second dielectric layer comprises a continuous second non-fluorinated polymeric material having a relatively lower dielectric constant, preferably less than 3, wherein the difference in the dielectric constants is at least 0.2, preferably at least 0.5, more preferably at least 0.8, for example 1.1. Preferably, the ratio of the dielectric constant of the higher to lower dielectric material is 5:1 to 1.1:1, more preferably between 3:1 and 1.1:1. In one embodiment of the invention, the first polymeric material has a dielectric constant greater than 3.0 and less than 10, preferably greater than 3.5 and up to 9, for example, 3.7, and the second non-fluorinated polymeric material has a dielectric constant from 2.3 to less than 3.0, preferably from greater than 2.3 to less than 2.8, for example, 2.6.

The first polymeric material can be selected, for example, from the following polymers:

TABLE 1

| | Dielectric Constant |
|---|---|
| Polymer | (low frequency, 50 Hz) |
| nylon-6 | 3.8 |
| nylon-66 | 8.0 |
| poly(vinylidene fluoride) or PVDF | 8.9 |
| Poly(ethylene terephthalate or PET | 4.0 |
| Polyimide or PI | 3.5 |
| Polyurethane or PUR | 3.6-6.6 |
| Poly(4-vinylphenol) | 3.7 |
| poly(vinyl acetate) | 3.3 |
| poly(methyl a-chloroacrylate) | 3.4 |
| poly(ethyl a-chloroacrylate) | 3.1 |
| Polyacrylonitrile | 3.1 |
| poly(methylene oxide) | 3.1 |
| poly(hexamethylene adipamide) | 4.0 |

Preferably, the first polymeric material is selected from the group consisting of poly(4-vinylphenol), polyimide, and poly(vinylidene fluoride), most preferably poly(4-vinylphenol).

The second polymeric material can be selected, for example, from the group consisting of the following non-fluorinated polymers having a dielectric constant above 2.3.

TABLE 2

| | Dielectric Constant |
|---|---|
| Polymer | (low frequency, 50 Hz) |
| Polystyrene | 2.5 |
| Poly(1-vinyl naphthalene) | 2.6 |
| Poly(1-methyl styrene) | 2.6 |
| Poly(o-chlorostyrene) | 2.6 |
| Poly(vinyl chloride) | 2.8 |
| Poly(methyl methacrylate) | 2.6 |
| Poly(ethyl methacrylate) | 2.7 |
| Poly(2,6-dimethylphenylene oxide) | 2.6 |
| Poly(bisphenol carbonate) | 2.6 |
| Poly(cis-butadiene) | 2.0 |
| Poly(cyclohexyl methacrylate) | 2.5 |
| Parylene | 2.6 |

Preferably, the second non-fluorinated polymeric material is selected from the group consisting of polystyrene and substituted derivatives thereof, poly(vinyl naphthalene) and substituted derivatives, and poly(methyl methacrylate), most preferably poly(vinyl naphthalene).

In a particularly preferred embodiment, the first polymeric material is poly(4-vinylphenol) and the second non-fluorinated polymeric material is poly(vinyl naphthalene).

The source electrode and drain electrode are separated from the gate electrode by the gate dielectric, while the organic semiconductor layer can be over or under the source electrode and drain electrode. The source and drain electrodes can be any useful conductive material. Useful materials include most of those materials described above for the gate electrode, for example, aluminum, barium, calcium, chromium, gold, silver, nickel, palladium, platinum, titanium, polyaniline, PEDOT:PSS, other conducting polymers, alloys thereof, combinations thereof, and multilayers thereof.

The thin film electrodes (e.g., gate electrode, source electrode, and drain electrode) can be provided by any useful means such as physical vapor deposition (e.g., thermal evaporation, sputtering) or ink jet printing. The patterning of these electrodes can be accomplished by known methods such as shadow masking, additive photolithography, subtractive photolithography, printing, microcontact printing, and pattern coating.

The organic semiconductor layer can be provided over or under the source and drain electrodes, as described above in reference to the thin film transistor article. The present invention also provides an integrated circuit comprising a plurality of OTFTs made by the process described herein.

Organic materials for use as potential semiconductor channels in TFTs are disclosed, for example, in U.S. Pat. No. 5, 347,144 to Garnier et al., entitled “Thin-Layer Field-Effect Transistors with MIS Structure Whose Insulator and Semiconductors Are Made of Organic Materials.” Organic semiconductor materials, for use in TFTs to provide the switching and/or logic elements in electronic components, require significant mobilities, well above 0.01 cm²/Vs, and current on/off ratios (hereinafter referred to as “on/off ratios”) greater than 1000. Organic TFTs having such properties are capable of use for electronic applications such as pixel drivers for displays and identification tags. Most of the compounds exhibiting these desirable properties are “p-type” or “p-channel,” meaning that negative gate voltages, relative to the source voltage, are applied to induce positive charges (holes) in the channel region of the device. N-type organic semiconductor materials can also be used in TFTs as an alternative to p-type organic semiconductor materials, where the terminology “n-type” or “n-channel” indicates that positive gate voltages, relative to the source voltage, are applied to induce negative charges in the channel region of the device.

The performance of the device is principally based upon the charge carrier mobility of the semiconducting material and the current on/off ratio, so the ideal semiconductor should have a low conductivity in the off state, combined with a high charge carrier mobility (>1×10⁻³ cm² V⁻¹ s⁻¹). In addition, it can be important that the semiconducting material is relatively stable to oxidation i.e. it has a high ionization potential, as oxidation leads to reduced device performance.

A well known compound which has been shown to be an effective p-type semiconductor for OFETs is pentacene (see Nelson et al., Appl. Phys. Lett., 1998, 72, 1854). When deposited as a thin film by vacuum deposition, it was shown to have carrier mobilities in excess of 1 cm² V⁻¹ s⁻¹ with very high current on/off ratios greater than 10⁶.

Regio regular poly(3-hexylthiophene) has been reported with charge carrier mobility between 1×10⁻⁵ and 4.5×10⁻² cm² V⁻¹ s⁻¹, but with a rather low current on/off ratio (10-10³) [see Bao et al., Appl. Phys. Lett., 1996, 69, 4108]. In general, poly(3-alkylthiophenes) shows good solubility and is able to be solution processed to fabricate large area films. However, poly(3-alkylthiophenes) has relatively low ionization potentials and are susceptible to doping in air [see Sirringhaus et al. Adv. Solid State Phys., 1999, 39, 101].

Various organic semiconductor materials that can be used in the present invention include, for example, acenes, such as anthracene, tetracene, pentacene, and substituted pentacenes. Substituted acene compounds that are useful as organic semiconductors in the present invention comprise at least one substituent selected from the group consisting of electron-donating substituents (for example, alkyl, alkoxy, or thioalkoxy), halogen substituents, and combinations thereof. For example, useful substituted pentacenes include but are not limited to 2,9-dialkylpentacenes and 2,10-dialkylpentacenes, wherein the alkyl group has from 1 to 12 carbons; 2,10-dialkoxypentacenes; and 1,4,8,11-tetraalkoxypentacenes. Such substituted pentacenes are taught in the prior art. Examples of other useful organic semiconductors include, among others, perylenes, fullerenes, phthalocyanines, oligothiophenes, and substituted derivatives thereof. Particular organic semiconductor compounds include sexithiophene, α,ωdihexylsexithiophene, quinquethiophene, quaterthiophene, cto,dihexylquaterthiophene, α,ωdihexylquinquethiophene, poly(3-hexylthiophene), bis(dithienothiophene), anthradithiophene, dihexylanthradithiophene, polyacetylene, polythienylenevinylene, C₆₀, copper(II) hexadecafluorophthalocyanine, and N,N′-bis(pentadecafluoroheptylmethyl)naphthalene-1,4,5,8-tetracarboxylic diimide. In a preferred embodiment the organic semiconductor material is a compound containing a fused polycyclic aromatic hydrocarbon, preferably having at least 4 fused benzene rings, hydrocarbons may be substituted or unsubstituted. Pentacene or a derivative thereof is especially preferred.

In order to improve charge carrier transport in organic semiconductors, processes in which semiconducting molecules, for example pentacene or oligothiophenes, can be deposited in an ordered manner have been developed. This is possible, for example, by vacuum sublimation. Ordered deposition of the organic semiconductor increases the crystallinity of the semiconductor material. As a result of the improved π-π overlap between the molecules or the side chains, the energy barrier for the charge carrier transport can be lowered. By substituting the semiconducting molecular units by bulky groups in the deposition of the organic semiconductor from the liquid or gas phase, it is possible to produce domains that have liquid crystalline properties. Furthermore, synthesis processes in which as high a regioregularity as possible is achieved in the polymers by the use of asymmetric monomers have been developed.

The organic semiconductor materials used in the present invention can exhibit high performance under ambient conditions without the need for special chemical underlayers.

The entire process of making the thin film transistor or integrated circuit of the present invention can be carried out below a maximum support temperature of about 450° C., preferably below about 250° C., more preferably below about 200° C., and even more preferably below about 150° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports. Thus, the invention enables production of relatively inexpensive integrated circuits containing organic thin film transistors with significantly improved performance.

The process for fabricating a thin film semiconductor device, can comprise, not necessarily in the following order, the steps of:
(a) forming a gate electrode spaced apart from the semiconductor material;
(b) forming a first layer of a first polymeric dielectric material having a thickness of 100 to 500 nm in contact with the gate electrode;
(c) forming a second layer of a second non-fluorinated polymeric dielectric material having a thickness of 5 nm to 40 nm over the first layer of a dielectric not in contact with the gate electrode, wherein the second non-fluorinated polymeric dielectric material has a relatively lower dielectric constant than the first polymeric dielectric material, wherein the difference in the dielectric constants is at least 0.2;
(d) depositing, onto a substrate, a thin film of organic semiconductor material; and
(e) forming a spaced apart source electrode and drain electrode, wherein the source electrode and the drain electrode are separated by, and electrically connected with, the semiconductor film,

Preferably, the first dielectric layer comprises a continuous first polymeric material and the second dielectric layer comprises a continuous second non-fluorinated polymeric material having a relatively lower dielectric constant, less than 3, wherein the difference in the dielectric constants is at least 0.2, preferably at least 0.5, more preferably at least 1.0.

In one embodiment, the first and second dielectric materials are deposited over the substrate by solution-phase deposition, wherein the substrate has a temperature of no more than 200° C., preferably 100° C. during deposition. In a preferred embodiment, the process comprises, preferably but not necessarily in the following order, the following steps: (a) providing a support; (b) providing a gate electrode material over the substrate; (c) providing a first layer of a first polymeric dielectric material in contact with the gate electrode and a second layer of a second non-fluorinated polymeric dielectric material over the first layer of a dielectric not in contact with the gate electrode; (d) depositing the thin film of organic semiconductor material over the gate dielectric; and (e) providing a source electrode and a drain electrode contiguous to the thin film of organic semiconductor material.

The semiconducting materials or compounds used in the invention can be readily processed and are thermally stable to such as extent that they can be vaporized. The compounds possess significant volatility, so that vapor phase deposition, where desired, is readily achieved. Such compounds can be deposited onto substrates by vacuum sublimation or by solvent processing, including dip coating, drop casting, spin coating, blade coating.

Deposition by a rapid sublimation method is also possible. One such method is to apply a vacuum of 35 mtorr to a chamber containing a substrate and a source vessel that holds the compound in powdered form, and heat the vessel over several minutes until the compound sublimes onto the substrate. Generally, the most useful compounds form well-ordered films, with amorphous films being less useful.

Alternatively, for example, the semiconducting compounds described above can first be dissolved in a solvent prior to spin-coating or printing for deposition on a substrate.

Devices in which the multi-layer dielectrics of the invention are useful include thin film transistors (TFTs), especially organic field effect thin-film transistors. Also, such dielectrics can be used in various types of devices having organic p-n junctions, such as described on pages 13 to 15 of U.S. Pat. No. 2004,0021204 A1 to Liu, which patent is hereby incorporated by reference.

Electronic devices in which TFTs and other devices are useful include, for example, more complex circuits, e.g., shift registers, integrated circuits, logic circuits, smart cards, memory devices, radio-frequency identification tags, backplanes for active matrix displays, active-matrix displays (e.g. liquid crystal or OLED), solar cells, ring oscillators, and complementary circuits, such as inverter circuits. In an active matrix display, a transistor according to the present invention can be used as part of the voltage hold circuitry of a pixel of the display. In devices containing the TFTs of the present invention, such TFTs are operatively connected by means known in the art.

The present invention further provides a method of making any of the electronic devices described above. Thus, the present invention is embodied in an article that comprises one or more of the TFTs described.

Advantages of the invention will be demonstrated by the following examples, which are intended to be exemplary.

### EXAMPLES

A. Materials:

The substrates used in the examples were single crystal <100> orientation silicon wafers from MEMC Electronic Materials, Inc. (St. Peters, Mo.), which were heavily doped with Antimony, the wafer having a resistivity between 0.008 to 0.025 ohm/sq. Poly(4-vinylphenol), Mw˜20,000, poly(melamine-co-formnaldehyde) methylated, Mn˜511, polystyrene (secondary standard) Mn˜120,000, poly(l-vinylnaphthlene), Mn˜100,000, propylene glycol methyl ether acetate (PGMEA), as solvent, and pentacene, as a semiconductor material, were obtained from Aldrich Chemicals, Milwaukee, Wis. (Mw indicates weight average molecular weight and Mn indicates number average molecular weight. Unless otherwise indicated, the molecular weights refer to average molecular weight.)

B. Device Preparation

The wafer substrates were cleaned with Piranha solution (1/3 ratio of H₂O₂/H₂SO₄ mixture) for 10 min and rinsed thoroughly with high purity water. Then, the wafers were further cleaned with UV/ozone exposure for 6 min. The heavily doped silicon wafer serves as the gate electrode of transistors for experimental purposes. A solution mixture containing 5% wt of poly(4-vinylphenol) (“PVPh”) and 0.5% wt poly(melamine-co-formaldehyde) methylated (“PMFM”), as crosslinker, in PGMEA was spun-coat on the wafer at 500 RPM for 120 seconds. The samples were heated to 200° C. on a hotplate for 10 min to cure the films. The PVPh films have thickness of about 275 nm and contact angle with water of about 60 degrees. The samples were labeled as Sample A.

A 0.2% wt of polystyrene (secondary standard, Mn˜120,600) in toluene was spun-coated on Sample A at 500 RPM for 20 seconds and 2000 RPM for 40 seconds. The films were dried in air for 5 min and heated to 110° C. for 5 min. The polystyrene coatings have thickness of about 30 nm and surface contact angle with water of about 88 degrees. The samples were labeled as Sample B.

A 0.2% wt of poly(1-vinylnaphthlene) (PVN, Mn˜100,000) in toluene was spun-coated on Sample A at 500 RPM for 20 seconds and 2000 RPM for 40 seconds. The films were dry in air for 5 min and heated to 200° C. for 5 min. The PVN coatings have thickness of about 15 nm and surface contact angle with water of about 87 degrees. The samples were labeled as Sample C.

Sample A was exposed under O₂ plasma for 60 second and then treated with a 0.01% wt of octadecyltrichlorosilane (OTS) in heptane for overnight. The OTS self-assembled monolayers (SAMs) have a thickness of about 3 nm and a surface contact angle with water of about 100 degrees. The samples were labeled as Sample D.

The active organic semiconductor layer of pentacene was deposited on Samples A to D prepared above via vacuum deposition in a thermal evaporator. Pentacene was purified by a vacuum sublimation process at least once before use. The deposition rate was 0.1 Angstroms per second while the substrate temperature was held at 60° C. for most experiments. The thickness of the active layer was a typically about 40 nm. Gold source and drain contacts of thickness 50 nm were deposited through a shadow mask. The channel width was held at 500 microns, while the channel lengths were varied between 20 and 100 microns. Some experiments were performed to look at the effect of other contact materials.

C. Device Measurement and Analysis

Electrical characterization of the fabricated devices was performed with a Hewlett Packard HP 4145b® parameter analyzer.

For each experiment performed, between 4 and 10 individual devices were tested on each sample prepared, and the results were averaged. For each device, the drain current (Id) was measured as a function of source-drain voltage (Vd) for various values of gate voltage (Vg). For most devices, Vd was swept from 0 V to −50 V for each of the gate voltages measured, typically 0 V, −10V, −20V, −30 V, −40 V, and −50 V. In these measurements, the gate current (Ig) was also recorded to detect any leakage current through the device. Furthermore, for each device the drain current was measured as a function of gate voltage for various values of source-drain voltage. For most devices, Vg was swept from 0 V to −50 V for each of the drain voltages measured, typically −30 V, −40 V, and −50 V.

Parameters extracted from the data include field-effect mobility (g), threshold voltage (Vth), subthreshold slope (S), and the ratio of Ion/loff for the measured drain current. The field-effect mobility was extracted in the saturation region, where Vd>Vg−Vth. In this region, the drain current is given by the equation (see Sze in Semiconductor Devices—Physics and Technology, John Wiley & Sons (1981)):

$${I}_{d} = \frac{W}{2 L} μ {{C}_{ox} ( {V}_{g} - {V}_{th} )}^{2}$$

where W and L are the channel width and length, respectively, and Cₒₓ is the capacitance of the oxide layer, which is a function of oxide thickness and dielectric constant of the material. Given this equation, the saturation field-effect mobility was extracted from a straight-line fit to the linear portion of the √I_{d} versus Vg curve. The threshold voltage, Vₜₕ, is the x-intercept of this straight-line fit.

The log of the drain current as a function of gate voltage was plotted. Parameters extracted from the log I_{d}plot include the Iₒₙ/I_{off} ratio and the sub-threshold slope (S). The Iₒₙ/I_{off} ratio is simply the ratio of the maximum to minimum drain current, and S is the inverse of the slope of the I_{d} curve in the region over which the drain current is increasing (i.e. the device is turning on).

D. Results

The results in the following Table 3 were obtained.

TABLE 3

| | | μ | | | | |
|---|---|---|---|---|---|---|
| | Dielectrics | (cm²/Vs) | σ (μ) | Vₜₕ (V) | σ (Vₜₕ) | IₒₙI_{off} |
| Sample | PVP | 0.35 | 0.03 | −10.3 | 2.0 | 1.4 × 10⁴ |
| A | | | | | | |
| Sample | PS/PVP | 0.71 | 0.05 | −16.7 | 1.8 | 6.9 × 10⁴ |
| B | | | | | | |
| Sample | PVN/PVP | 0.79 | 0.06 | −18.2 | 1.4 | 3.1 × 10⁵ |
| C | | | | | | |
| Sample | OTS/PVP | 0.18 | 0.05 | −5.9 | 2.3 | 4.3 × 10⁴ |
| D | | | | | | |

The examples demonstrate that compared to single-layered polymeric gate dielectric OTFT devices as in Sample A, the multi-layered polymeric gate dielectric structure disclosed according to this invention, such as the devices in Sample B and C, gives much improved OTFT device performance as the mobility calculated in the saturation region was more than a factor of two higher, with an on/off ratio of 10⁴ to 10⁵. In comparison with the devices from Sample D, it is demonstrated that the conventional surface treatment with OTS on the gate dielectric surface to improve OTFT performance does not work with the polymeric gate dielectric materials such as PVP, and only the multilayered polymeric gate dielectric structure in this invention offers the solution for improvement of OTFT device performance. Surface treatment with OTS or other polymers is, therefore, not used.

1. An article comprising, in a thin film transistor, a thin film of organic semiconductor material wherein the thin film transistor is a field effect transistor comprising a multi-layer dielectric, a gate electrode, a source electrode, and a drain electrode, and wherein the multi-layer dielectric, the gate electrode, the thin film of organic semiconductor material, the source electrode, and the drain electrode are in any sequence as long as the gate electrode and the film of organic semiconductor material both contact the multi-layer dielectric, and the source electrode and the drain electrode both contact the thin film of the organic semiconductor material, wherein the multilayer dielectric comprises a first dielectric layer having a thickness of 100 to 500 nm, in contact with the gate electrode and a second dielectric layer having a thickness of 5 nm to 50 nm in contact with the organic semiconductor material, and wherein the first dielectric layer comprises a continuous first polymeric material having a relatively higher dielectric constant less than 10.0 and the second dielectric layer comprises a continuous second non-fluorinated polymeric material having a relatively lower dielectric constant of greater than 2.3, wherein the difference in the dielectric constants is at least 0.2.

2. The article of claim 1 wherein the ratio of the dielectric constant of the higher to lower dielectric material is 5:1 to 1.1:1.

3. The article of claim 1 wherein the second dielectric layer having a thickness of 5 nm to 40 nm and wherein the difference in the dielectric constants is at least 0.8 and wherein the ratio of the dielectric constant of the higher to lower dielectric material is between 3.0:1.0 and 1.1:1.0.

4. The article of claim 1 wherein the organic semiconductor material is made of a P-type semiconductor material containing a fused polycyclic aromatic hydrocarbon having at least three fused benzene rings.

5. The article of claim 1 wherein the organic semiconductor material is made of pentacene or a derivative thereof.

6. The article of claim 1 wherein the first polymeric material has a dielectric constant of between 3.0 and 10.0 and the second non-fluorinated polymeric material has a dielectric constant of not more than 3.0.

7. The article of claim 1 wherein the first polymeric material is selected from the group consisting of poly(4-vinylphenol), polyimide, and poly(vinylidene fluoride).

8. The article of claim 7 wherein the first polymeric material is selected from the group consisting of poly(4-vinylphenol).

9. The article of claim 1 wherein the second non-fluorinated polymeric material is selected from the group consisting of polystyrene and derivatives thereof, poly(vinyl naphthalene) and derivatives, and poly(methyl methacrylate).

10. The article of claim 9 wherein the second non-fluorinated polymeric material is selected from the group consisting of poly(vinyl naphthalene) and derivatives.

11. The article of claim 10 wherein the second non-fluorinated polymeric material is selected from the group consisting of poly(vinyl naphthalene) and the first polymeric material is a polymer with a dielectric constant greater than 3.0 and less than 10.

12. The article of claim 1, wherein the gate electrode is adapted for controlling, by means of a voltage applied to the gate electrode, a current between the source and drain electrodes through the organic semiconductor material.

13. The article of claim 1 wherein the thin film transistor further comprises a non-participating support that is optionally flexible.

14. The article of claim 1 wherein the source, drain, and gate electrodes each independently comprising a material selected from doped silicon, metal, and a conducting polymer.

15. An electronic device selected from the group consisting of integrated circuits, active-matrix display, and solar cells comprising a multiplicity of thin film transistors according to claim 1.

16. The electronic device of claim 15 wherein the multiplicity of the thin film transistors is on a non-participating support that is optionally flexible.

17. A process for fabricating a thin film semiconductor device, comprising, not necessarily in the following order, the steps of:
(a) forming a gate electrode spaced apart from a semiconductor material;
(b) forming a first layer of a first polymeric dielectric material having a thickness of 100 to 500 nm in contact with the gate electrode;
(c) forming a second layer of a second non-fluorinated polymeric dielectric material having a thickness of 5 nm to 50 nm over the first layer of a dielectric not in contact with the gate electrode;
(d) depositing, onto a substrate, a thin film of organic semiconductor material; and
(e) forming a spaced apart source electrode and drain electrode, wherein the source electrode and the drain electrode are separated by, and electrically connected with, the semiconductor film;
wherein the first dielectric layer comprises a continuous first polymeric material having a relatively higher dielectric constant less than 10.0, and the second dielectric layer comprises a continuous second non-fluorinated polymeric material having a relatively lower dielectric constant of greater than 2.3 and wherein the difference in the dielectric constants is at least 0.2.

18. The process of claim 17, wherein the first and the second dielectric materials are deposited over the substrate by solution-phase deposition and wherein the substrate has a temperature of no more than 200 and the process comprises, not necessarily in order, the following steps:
(a) providing a support;
(b) providing a gate electrode material over the substrate;
(c) providing a first layer of a first polymeric dielectric material in contact with the gate electrode and a second layer of a second non-fluorinated polymeric dielectric material over the first layer of a dielectric not in contact with the gate electrode;
(d) depositing the thin film of organic semiconductor material over the gate dielectric; and
(e) providing a source electrode and a drain electrode contiguous to the thin film of organic semiconductor material.

19. The process of claim 17 wherein the organic semiconductor material is made of a P-type semiconductor material containing a fused polycyclic aromatic hydrocarbon having at least three fused benzene rings.

20. An integrated circuit comprising a plurality of thin film transistors according to claim 1.
